(19) United States
(12) Patent Application Publication
(10) Pub. No.: US 2025/0007475 A1
(43) Pub. Date: Jan. 2, 2025

(54) Calibration circuit of differential difference amplifier

(71) Applicant: NOVATEK Microelectronics Corp., Hsin-Chu (TW)

(72) Inventors: Jui-Chan Chang, Hsinchu City (TW); Jhih-Siou Cheng, New Taipei City (TW); Ren-Chieh Yang, Hsinchu County (TW); Jin-Yi Lin, Kaohsiung City (TW)

(73) Assignee: NOVATEK Microelectronics Corp., Hsin-Chu (TW)

(21) Appl. No.: 18/624,110

(22) Filed: Apr. 1, 2024

Related U.S. Application Data
(60) Provisional application No. 63/523,650, filed on Jun. 28, 2023.
(60) Provisional application No. 63/598,149, filed on Nov. 13, 2023.

(51) Int. Cl. H03F 3/45

(52) U.S. Cl. CPC H03F 3/45475

(57) ABSTRACT

A calibration circuit of a differential difference amplifier (DDA) includes a trimming circuit, a bias generator and a compensation output circuit. The trimming circuit is used to output a trimming code. The bias generator, coupled to the trimming circuit, is used to generate a bias current or voltage according to the trimming code. The compensation output circuit, coupled to the bias generator, is used to receive a data code of the DDA and output the bias current or voltage corresponding to the data code to the DDA.

### CROSS REFERENCE TO RELATED APPLICATIONS

This application claims the benefit of U.S. Provisional Application No. 63/523,650, filed on Jun. 28, 2023. Further, this application claims the benefit of U.S. Provisional Application No. 63/598,149, filed on Nov. 13, 2023. The contents of these applications are incorporated herein by reference.

### BACKGROUND OF THE INVENTION

### 1. Field of the Invention

The present invention relates to a calibration circuit of a differential difference amplifier (DDA), and more particularly, to a calibration circuit for calibrating the output voltage of the DDA.

### 2. Description of the Prior Art

Since modern display panels develop towards a wide color gamut, the requirements of output grayscales of the display driver integrated circuit (DDIC) also increases. The increase of grayscales will lead to a increase of significant the area of the digital-to-analog converters (DACs) implemented in the source driver of the DDIC, thereby increasing the costs of the DDIC. The differential difference amplifier (DDA) is a solution for saving the usage of DACs. However, the output voltage range of a DDA is limited due to its linearity issue. Although the grayscale values keep increasing, the performance of the DDA's output cannot keep pace with the increasing grayscale values. In such a situation, the circuit area of the DDIC may still increase following the increasing grayscales. Thus, there is a need for improvement over the prior art.

### SUMMARY OF THE INVENTION

It is therefore an objective of the present invention to provide a calibration circuit for calibrating the output voltage of a differential difference amplifier (DDA), so as to improve the linearity of the DDA's output. This helps improve the output accuracy of the DDA and also increase the output range of the DDA.

An embodiment of the present invention discloses a calibration circuit of a DDA, where the calibration circuit comprises a trimming circuit, a bias generator and a compensation output circuit. The trimming circuit is used to output a trimming code. The bias generator, coupled to the trimming circuit, is used to generate a bias current or voltage according to the trimming code. The compensation output circuit, coupled to the bias generator, is used to receive a data code of the DDA and output the bias current or voltage corresponding to the data code to the DDA.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a source driver of a display driver circuit.

FIG. 2 illustrates an exemplary implementation of the SOP to realize the DDA operations.

FIG. 3 illustrates the relation of the output voltage versus the data code in a DDA operation.

FIG. 4 illustrates an error curve generated in the DDA operation.

FIG. 5 is a schematic diagram of a calibration circuit according to an embodiment of the present invention.

FIG. 6 illustrates the compensation values corresponding to the DDA errors in a voltage range of several data codes.

FIG. 7 is a schematic diagram of an SOP which is controlled by a calibration circuit to compensate for the DDA errors according to an embodiment of the present invention.

FIG. 8 illustrates an implementation of bias control for a current source array included in the input stage of the SOP.

FIG. 9 is a schematic diagram of an SOP which is controlled by another calibration circuit to compensate for the DDA errors according to an embodiment of the present invention.

FIG. 10 illustrates an exemplary implementation of the auxiliary input pair.

### DETAILED DESCRIPTION

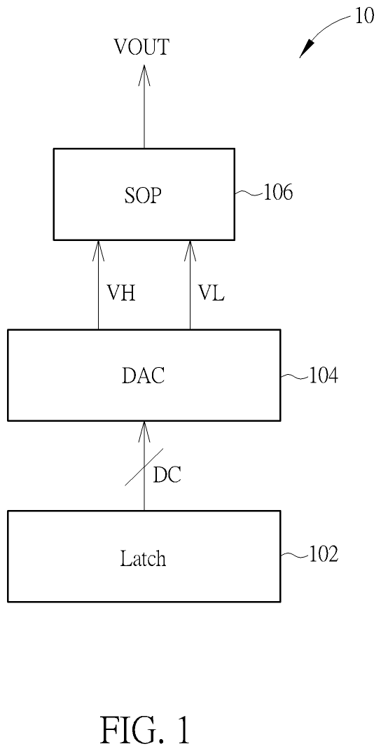

FIG. 1 is a schematic diagram of a source driver 10 of a display driver circuit, which may be implemented in a display driver integrated circuit (DDIC). The source driver 10 includes a latch circuit 102, a digital-to-analog converter (DAC) 104 and a source operational amplifier (SOP) 106. The SOP 106 is a differential difference amplifier (DDA) capable of performing interpolation on the received input voltages (including a high voltage VH and a low voltage VL) to generate an output voltage VOUT.

In the source driver 10, the latch circuit 102 may output a data code DC to the DAC 104. Based on the DDA operations, the DAC 104 may output a high voltage VH and a low voltage VL corresponding to several bits of the data code DC received from the latch circuit 102. The SOP 106 thereby generates the output voltage VOUT according to the high voltage VH and the low voltage VL, where the output voltage VOUT may be a voltage between the high voltage VH and the low voltage VL generated through interpolation. The interpolation may be performed based on other bits of the data code DC.

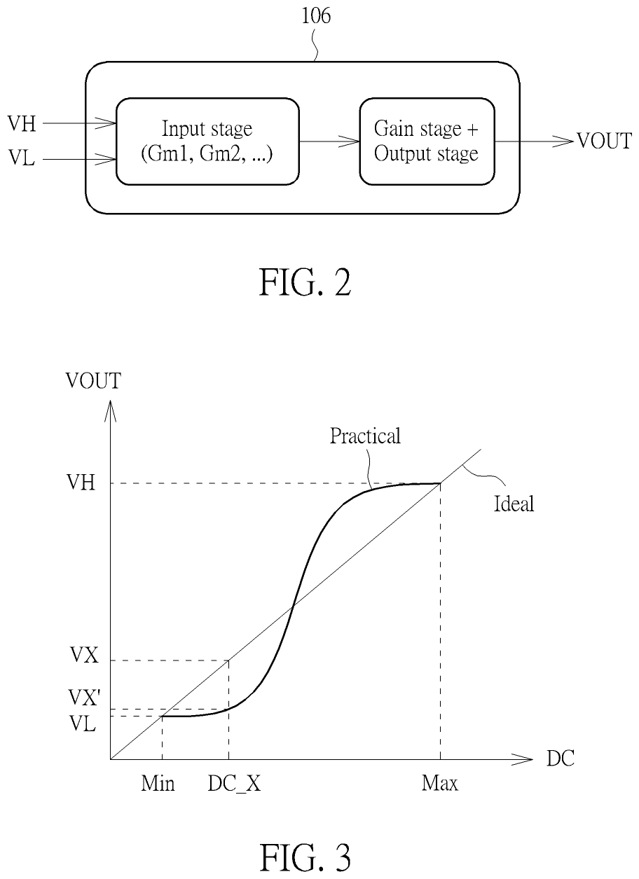

FIG. 2 illustrates an exemplary implementation of the SOP 106 to realize the DDA operations. As shown in FIG. 2, the SOP 106 may be generally divided into an input stage, a gain stage and an output stage. In this embodiment, the DDA operations may be implemented in the input stage, in which the transconductances Gm1, Gm2 . . . may be modified according to the data code, to generate an interpolation voltage as the output voltage VOUT. In general, by receiving N bits of the data code DC, the SOP 106 may perform N-bit interpolation to generate the output voltage VOUT, where N may be any appropriate integer. For example, if a 4-bit DDA operation is applied, the SOP 106 is able to generate 16 different output voltages VOUT between the high voltage VH and the low voltage VL, and the voltage step will be approximately 1/16 of the voltage difference of VH and VL. The values of the transconductances Gm1, Gm2 . . . may be preconfigured to appropriate values to generate the desired values of the output voltage VOUT. In an embodiment, the values of the transconductances Gm1, Gm2 . . . may be modified by controlling the current sources for supplying bias currents to input pairs in the input stage.

However, when the bit number used for interpolation increases, the linearity of the output voltage VOUT will be degraded; that is, the voltage step between two adjacent values of the output voltage VOUT might be deviated from 1/16 of the voltage difference of VH and VL in the 4-bit DDA operation. For example, as shown in FIG. 3, the SOP 106 may receive the high voltage VH and the low voltage VL to perform interpolation in response to the data code DC, where the high voltage VH may correspond to a maximum data code (Max) and the low voltage VL may correspond to a minimum data code (Min). In the range between the high voltage VH and the low voltage VL, the relation of the output voltage VOUT versus the data code DC should be a straight line ideally. However, in a practical circuit implementation of the SOP 106, the relation of the output voltage VOUT versus the data code DC may be non-linear, resulting in a non-linear curve as shown in FIG. 3. For example, as for a data code DC_X, the SOP 106 is predicted to output the output voltage VOUT equal to Vx ideally, but the non-linear relationship causes that the output voltage VOUT is equal to Vx′.

This non-linear relationship may originate from the transconductance of the SOP 106, which may be generated from the input transistors in the input stage, where the input transistors have a non-linear voltage-to-current transition behavior. More specifically, the input stage aims at generating a differential current to be supplied to the gain stage, where the differential current value is determined based on the input voltages (i.e., VH and VL) and the transconductance values of the SOP 106. The transition from the input voltages to the differential current may follow a square law of the input transistors that may not be linear. In such a situation, the interpolation voltage generated based on the variations of the transconductance values may also possess the non-linear characteristics, which generates a DDA error on the output voltage VOUT.

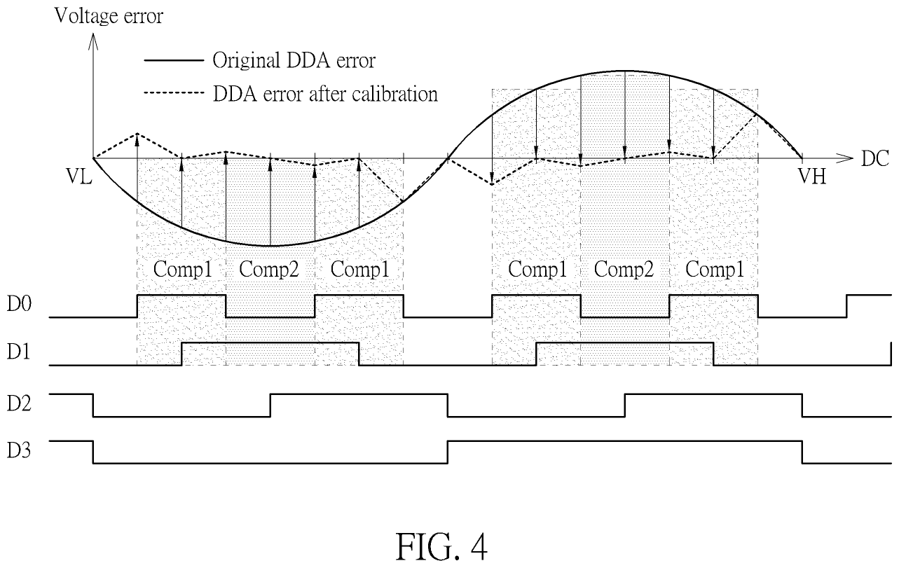

The DDA error may also be represented by an error curve in the range between the high voltage VH and the low voltage VL, where the error curve may be obtained in 4 data codes D0-D3 if a 4-bit DDA operation is applied, as shown in FIG. 4. If there is no DDA error, the curve should be exactly on the level of 0V from VL to VH. The error curve shown in FIG. 4 indicates that there is a negative error in the lower half range and a positive error in the upper half range. The pattern of the error curve may be derived from the I-V curve of the input transistors in the input stage of the SOP 106 based on the DDA interpolation scheme. Note that different DDA interpolation schemes performed in the SOP 106 may generate different error curves. In order to improve the linearity of the output voltage VOUT, it is requested to apply a compensation value (e.g., Comp1 or Comp2) to compensate for the error term and calibrate the output voltage VOUT. After the calibration, the error curve will be closer to 0 in each voltage step between VH and VL, which means that the DDA error is reduced.

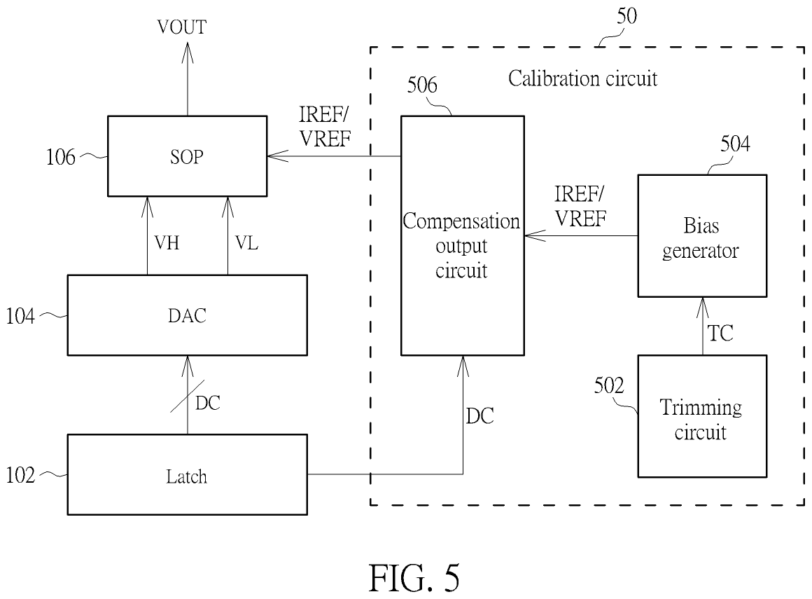

The present invention provides a calibration circuit for the DDA, to improve the linearity of the output voltage VOUT output by the SOP 106. FIG. 5 is a schematic diagram of a calibration circuit 50 according to an embodiment of the present invention, where the SOP 106, the DAC 104 and the latch circuit 102 of the source driver 10 are also shown in FIG. 5 to facilitate the illustrations. The calibration circuit 50 may be used for calibrating the output voltage VOUT of the SOP 106. In an embodiment, the calibration circuit 50 may be implemented along with the source driver 10 in the DDIC.

As shown in FIG. 5, the calibration circuit 50 includes a trimming circuit 502, a bias generator 504 and a compensation output circuit 506. The trimming circuit 502 is configured to output a trimming code TC, which is used for determining a bias current IREF and/or a bias voltage VREF for the SOP 106. The bias generator 504, which is coupled to the trimming circuit 502, may generate the bias current IREF and/or the bias voltage VREF according to the trimming code TC. The compensation output circuit 506, which is coupled to the bias generator 504, may receive a data code DC of the SOP 106 and output the bias current IREF and/or the bias voltage VREF corresponding to the data code DC to the SOP 106. As shown in FIG. 5, the compensation output circuit 506 may be coupled to the latch circuit 102, to receive the data code DC from the latch circuit 102.

Referring back to FIG. 4, different data codes DC have different error terms, and thus require different compensation values (e.g., Comp1 or Comp2). The trimming circuit 502 may provide a trimming code TC to be applied to each data code value, allowing the bias generator 504 to generate the desired bias current IREF and/or bias voltage VREF for the data code value. The compensation output circuit 506 will obtain the data code DC from the latch circuit 102, and correspondingly output the bias current IREF and/or bias voltage VREF to compensate for the error term of this data code value.

In an embodiment, the output voltage VOUT of the SOP 106 may be measured to determine the corresponding DDA errors. For example, when the calibration circuit 50 is not included, the output voltage VOUT may be measured for each data code DC in the voltage range between the high voltage VH and the low voltage VL. The measurement result may be applied to determine the trimming code TC, so that the corresponding bias current IREF and/or bias voltage VREF may be used to compensate for the DDA errors.

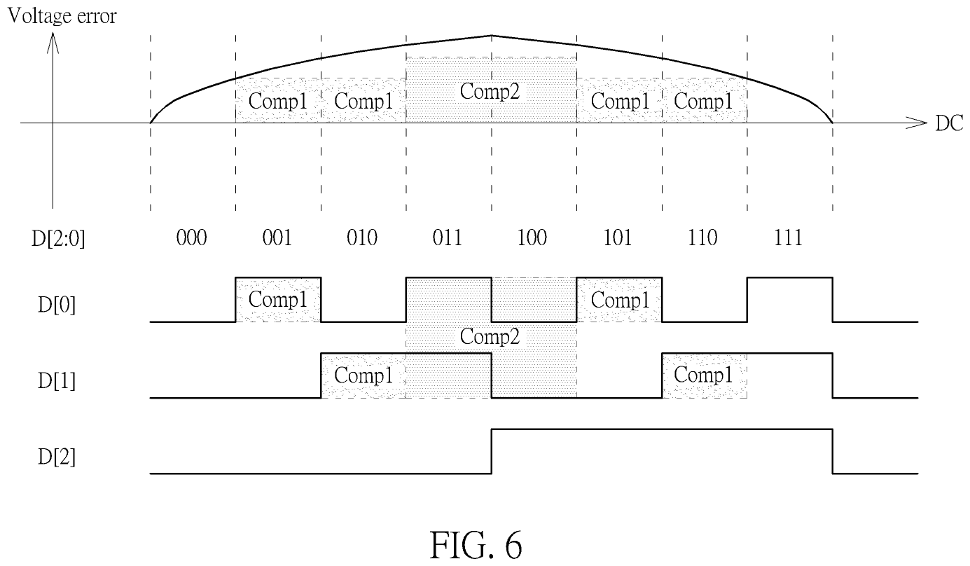

FIG. 6 illustrates the compensation values corresponding to the DDA errors in a voltage range of several data codes. As shown in FIG. 6, the SOP 106 may receive data bits D [2:0] to perform a 3-bit DDA operation, where the error curve is also shown in FIG. 6. As for the data code value D [2:0]=000, the measured error is quite small, and the calibration circuit 50 may determine that no compensation is required. As for the data code value D [2:0]=001, the measurement result of the output voltage VOUT indicates that the error term increases to a non-ignorable level; hence, the trimming circuit 502 may output a first trimming code, which controls the bias generator 504 to modify the output bias current IREF or bias voltage VREF. In this embodiment, the bias current IREF or bias voltage VREF may generate an appropriate compensation value Comp1, thereby decreasing the error term after calibration.

In the similar manner, as for the data code value D [2:0]=011, the measurement result of the output voltage VOUT indicates that the error term further increases; hence, a second trimming code may be output by the trimming circuit 502, in order to control the bias generator 504 to further adjust the output bias current IREF or bias voltage VREF. The bias current IREF or bias voltage VREF may generate a larger compensation value Comp2 to further decrease the error term after calibration.

In such a situation, after measurement, the calibration circuit 50 may determine appropriate compensation values for all the data code values D [2:0] from 000 to 111 in the DDA operations. In an embodiment, the trimming codes corresponding to these compensation values for different data codes may be stored as a look-up table (LUT) in a memory, which may be included in the trimming circuit 502. Therefore, when the compensation output circuit 506 obtains the data code to be used for the SOP 106 from the latch circuit 102, it may also obtain the corresponding trimming code TC, or obtain the bias settings corresponding to the trimming code TC, in order to output the corresponding bias current IREF and/or bias voltage VREF.

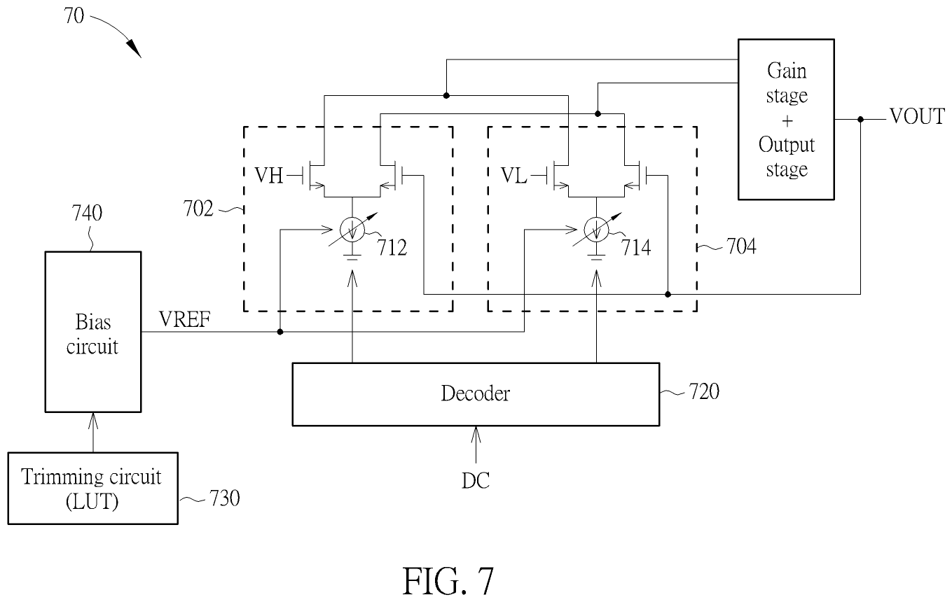

FIG. 7 is a schematic diagram of an SOP 70 which is controlled by a calibration circuit to compensate for the DDA errors according to an embodiment of the present invention. The SOP 70 includes an input stage, a gain stage and an output stage, where a detailed implementation of the input stage is shown in FIG. 7. As mentioned above, the DDA operation may be performed on the input stage of the SOP 70. The input stage includes at least two input pairs, among which an input pair 702 receives the high voltage VH and another input pair 704 receives the low voltage VL. Each of the input pairs 702 and 704 receives a current from a voltage-controlled current source (VCCS) 712 and 714, respectively, where the VCCSs 712 and 714 are controlled by a bias voltage VREF.

As shown in FIG. 7, the SOP 70 is calibrated by using a calibration circuit, which includes a decoder 720, a trimming circuit 730 and a bias circuit 740. The decoder 720 may be implemented in the compensation output circuit of the calibration circuit, such as the compensation output circuit 506 shown in FIG. 5. The trimming circuit 730, which may be an implementation of the trimming circuit 502 shown in FIG. 5, may include an LUT or may be coupled to an LUT for storing the trimming codes. The bias circuit 740 may be an implementation of the bias generator 504 and the compensation output circuit 506 shown in FIG. 5.

The input pair 702 includes the VCCS 712 for the current supply of the input pair 702, and the input pair 704 includes the VCCS 714 for the current supply of the input pair 704. Note that this is merely a conceptual illustration. In fact, in the input stage, the VCCS 712 of the input pair 702 may refer to a combination of one or more VCCSs configured to supply currents to the input transistors of the input pair 702 that receive the high voltage VH, and the VCCS 714 of the input pair 704 may refer to a combination of one or more VCCSs configured to supply currents to the input transistors of the input pair 704 that receive the low voltage VL. As shown in FIG. 7, the decoder 720 may receive a data code DC to be used for the SOP 70, and decode the data code DC to determine how many VCCSs should be contained in the VCCS 712 and how many VCCSs should be contained in the VCCS 714. In the voltage range between VH and VL, a lower output voltage VOUT may be generated in response to a smaller data code DC, and thus more VCCSs in the input stage will be switched to the input pair 704 receiving the low voltage VL, to generate an interpolated output voltage VOUT closer to VL; a higher output voltage VOUT may be generated in response to a larger data code DC, and thus more VCCSs in the input stage will be switched to the input pair 702 receiving the high voltage VH, to generate an interpolated output voltage VOUT closer to VH.

Each of the VCCSs 712 and 714 may receive the bias voltage VREF from the bias circuit 740. The trimming circuit 730 may output a trimming code TC to control the bias circuit 740 to provide the bias voltage VREF for each VCCS included in 712 and 714.

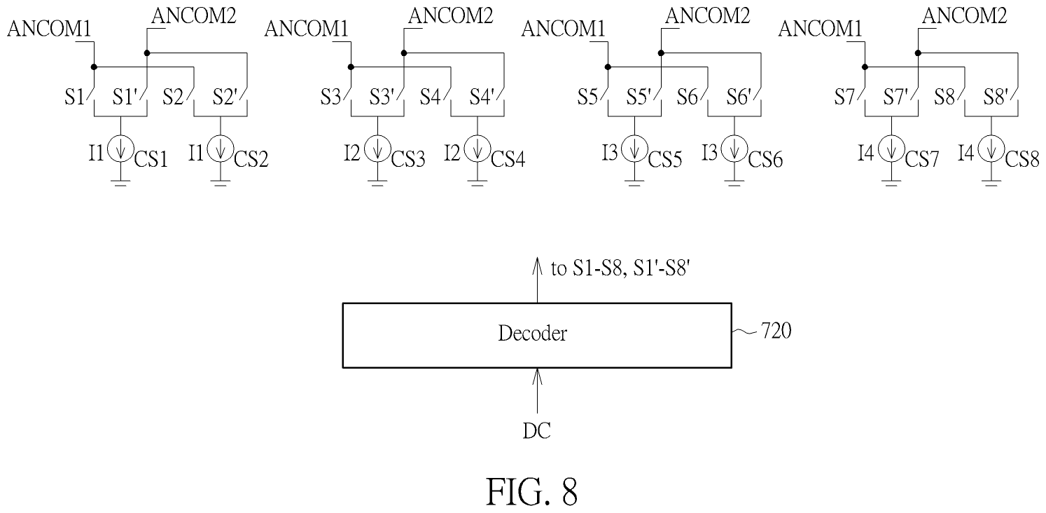

FIG. 8 illustrates an implementation of bias control for a current source array included in the input stage of the SOP 70. As shown in FIG. 8, in order to realize a 3-bit DDA, there may be 8 VCCSs CS1-CS8 included in the input stage, and each VCCS CS1-CS8 may supply identical or different currents. In this embodiment, two VCCSs CS1 and CS2 are configured to supply a current I1, two VCCSs CS3 and CS4 are configured to supply a current I2, two VCCSs CS5 and CS6 are configured to supply a current I3, and two VCCSs CS7 and CS8 are configured to supply a current I4. Each of the VCCSs CS1-CS8 may be controlled by two switches (one of S1-S8 and one of S1′-S8′), respectively, to be selectively coupled to a common node ANCOM1 or ANCOM2. The common node ANCOM1 may refer to the common node of the input pair 702, and the common node ANCOM2 may refer to the common node of the input pair 704.

The decoder 720 may allocate the VCCSs CS1-CS8 according to the data code DC. More specifically, the decoder 720 may decode the data code DC to output control signals to the corresponding switches S1-S8 and S1′-S8′, to control the VCCSs CS1-CS8 to be selectively coupled to the common node ANCOM1 or ANCOM2. The VCCSs coupled to the same common node may be considered as combined in parallel, and their output currents may be summed up.

Therefore, each of the VCCSs CS1-CS8 may be switched between a component of 712 and a component of 714 by following Table 1 to realize the 3-bit DDA operation, in order to generate a desired output voltage VOUT of the SOP 70 corresponding to different data codes DC. In this embodiment, each VCCS CS1-CS8 may supply an identical current ideally, i.e., I1=I2=I3=I4. Therefore, the output voltage VOUT may be determined according to the number of VCCSs switched to be coupled to the common node ANCOM1 to supply currents to the input pair 702 and the number of VCCSs switched to be coupled to the common node ANCOM2 to supply currents to the input pair 704. For example, as for the 3-bit DDA operation, the data code DC for interpolation may be represented by a 3-bit code in a DDA cycle ranging from 0 (000) to 7 (111). If the code is 0, all VCCSs CS1-CS8 are switched to the input pair 704, and the output voltage VOUT will be equal to the low voltage VL. If the code is 1, there are 7 VCCSs switched to the input pair 704 and only 1 VCCS switched to the input pair 702, the output voltage VOUT will be substantially equal to ⅞×VL+⅛×VH. A detailed implementation is shown in Table 1.

TABLE 1

| DC | 702/712 | 704/714 | VOUT |
|---|---|---|---|
| 0 | 0 | 2 × I1 + 2 × I2 + 2 × I3 + 2 × I4 | VL |
| 1 | 1 × I1 | 1 × I1 + 2 × I2 + 2 × I3 + 2 × I4 | 7/8 × VL + 1/8 × VH |
| 2 | 1 × I1 + 1 × I2 | 1 × I1 + 1 × I2 + 2 × I3 + 2 × I4 | 6/8 × VL + 2/8 × VH |
| 3 | 1 × I1 + 1 × I2 + 1 × I3 | 1 × I1 + 1 × I2 + 1 × I3 + 2 × I4 | 5/8 × VL + 3/8 × VH |
| 4 | 1 × I1 + 1 × I2 + 1 × I3 + 1 × I4 | 1 × I1 + 1 × I2 + 1 × I3 + 1 × I4 | 4/8 × VL + 4/8 × VH |
| 5 | 1 × I1 + 1 × I2 + 1 × I3 + 2 × I4 | 1 × I1 + 1 × I2 + 1 × I3 | 3/8 × VL + 5/8 × VH |
| 6 | 1 × I1 + 1 × I2 + 2 × I3 + 2 × I4 | 1 × I1 + 1 × I2 | 2/8 × VL + 6/8 × VH |
| 7 | 1 x I1 + 2 × I2 + 2 × I3 + 2 × I4 | 1 × I1 | 1/8 × VL + 7/8 × VH |

However, if the values of the currents I1-I4 are exactly identical, the output voltage VOUT may be slightly deviated from its desired values, to generate the error terms and error curve such as those shown in FIG. 6. In order to compensate for the DDA errors, several of the currents I1-I4 may be finely tuned to have slightly different values, and the values of the currents I1-I4 may be adjusted by using the trimming codes. As mentioned above, the output voltage VOUT may be measured for each data code DC (e.g., from 0 to 7) in the voltage range between the high voltage VH and the low voltage VL. Based on the measurement result, the values of the currents I1-I4 may be adjusted to target values, and their combinations may make the output voltage VOUT closer to its ideal value for each data code after the trimming and calibration operations. For example, the default value of the currents I1-I4 may be 1 nanoampere (nA). After the trimming operations, the values of the currents I1-I4 may be tuned to 0.9 nA, 1.1 nA, 1.05 nA and 1 nA, respectively.

The current values of I1-I4 may be adjusted by controlling the bias voltages VREF to be output to the VCCSs CS1-CS8 based on the trimming codes. The trimming codes for generating these current values may be stored in the LUT of the trimming circuit 730. Based on the data code DC obtained from the decoder 720, the trimming circuit 730 may select appropriate trimming codes from those stored in the LUT to be used for the corresponding VCCSs CS1-CS8. The bias circuit 740 may correspondingly output the bias voltages VREF to the VCCSs CS1-CS8 based on the trimming codes, to control the VCCSs CS1-CS8 to generate the target values of the currents I1-I4. The VCCSs CS1-CS8 may output identical or different current values by receiving the same or different bias voltages VREF.

Therefore, when the input data code DC changes, the decoder 720 may control the VCCSs CS1-CS8 to be switched accordingly. With the adjustment of the current values of I1-I4 and appropriate allocations of the VCCSs CS1-CS8, the generated output voltage VOUT will be much closer to its target value corresponding to the data code DC. As a result, the output voltage VOUT in the interested range will be much linear, and the DDA errors may be minimized.

Note that on different display panels, the output voltages for generating the same desired brightness may be different and may be obtained in a gamma tuning process before the display panel products leave the factory. Similarly, the behavior of the DDA errors on different display panels may also be different; hence, the trimming operations, including measuring the data voltage for each data code and calculating the trimming codes, may be completed before the display panel products leave the factory. Therefore, the current values of the VCCSs may be adjusted to desired values before the display panel products start to be used, where the DDICs for different display panels might have different suitable trimming codes.

Also note that the above implementation of the calibration circuit shown in FIGS. 7 and 8 is one of various embodiments of the present invention. In another embodiment, the calibration circuit may use the trimming code to control the bias voltage/current in another manner.

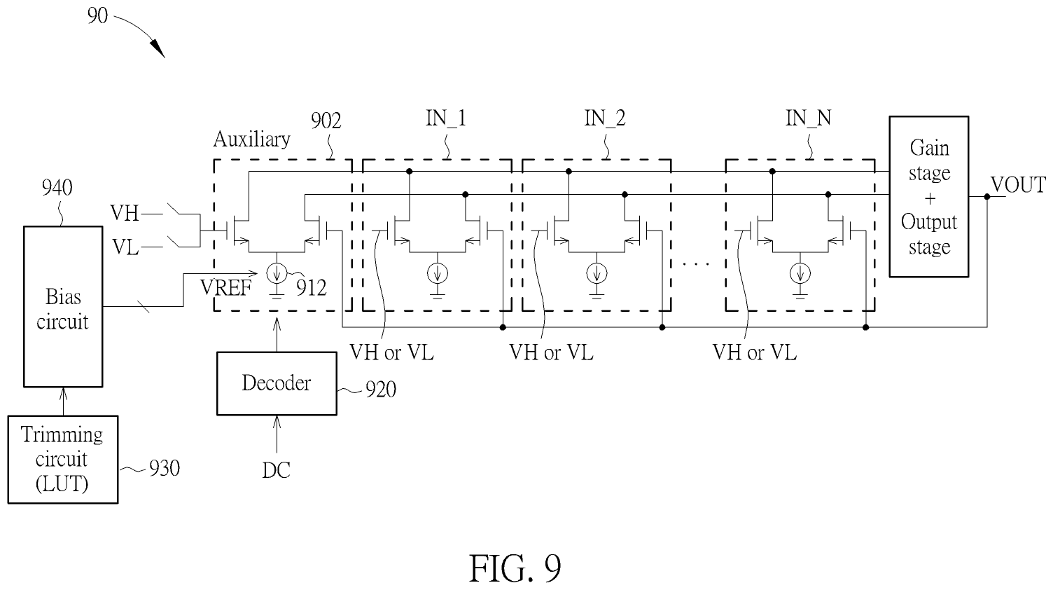

FIG. 9 is a schematic diagram of an SOP 90 which is controlled by another calibration circuit to compensate for the DDA errors according to an embodiment of the present invention. The SOP 90 may realize the DDA operations by applying multiple basic input pairs IN_1-IN_N having different transconductance weightings in its input stage. Each basic input pair IN_1-IN_N may be arranged to receive the high voltage VH or the low voltage VL according to the received data code DC, in order to generate the desired output voltage VOUT through interpolation.

In addition to the basic input pairs IN_1-IN_N, the input stage of the SOP 90 may further include one or more auxiliary input pairs 902, where the basic input pairs IN_1-IN_N and the auxiliary input pair 902 commonly supply a differential current to the gain stage. The auxiliary input pair 902 may selectively receive the high voltage VH or the low voltage VL to generate an incremental value or a decremental value for the output voltage VOUT. The auxiliary input pair 902 may have one or more current sources such as VCCSs 912, which may receive a bias voltage VREF to generate desired output current values. The output currents of the VCCSs 912 will become a component of the differential current to be delivered to the gain stage, so as to adjust the output voltage VOUT of the SOP 90.

As shown in FIG. 9, the SOP 90 is calibrated by using a calibration circuit, which includes a decoder 920, a trimming circuit 930 and a bias circuit 940. Similarly, the decoder 920 may be implemented in the compensation output circuit of the calibration circuit, such as the compensation output circuit 506 shown in FIG. 5. The trimming circuit 930, which may be an implementation of the trimming circuit 502 shown in FIG. 5, may include an LUT or may be coupled to an LUT for storing the trimming codes. The bias circuit 940 may be an implementation of the bias generator 504 and the compensation output circuit 506 shown in FIG. 5.

In a similar manner, the current values of the VCCSs 912 in the auxiliary input pair 902 may be modified by using the trimming codes, which may be obtained through measurement and stored in the LUT of the trimming circuit 930. The operations of the VCCSs 912 may be controlled by the decoder 920, which receives the data code DC (e.g., from the latch circuit) and decodes the data code DC to generate control signals for controlling the VCCSs 912 in the auxiliary input pair 902. In addition, the bias circuit 940 may output the bias voltage VREF to the VCCSs 912, to control the VCCSs 912 to supply desired currents.

From another perspective, the VCCSs 912 may be regarded as being implemented along with the bias circuit 940 in the compensation output circuit of f the calibration circuit. Therefore, the compensation output circuit is configured to output a bias current (i.e., an output current of the VCCSs 912) to the auxiliary input pair 902, where the value of the bias current may be adjusted based on the trimming codes.

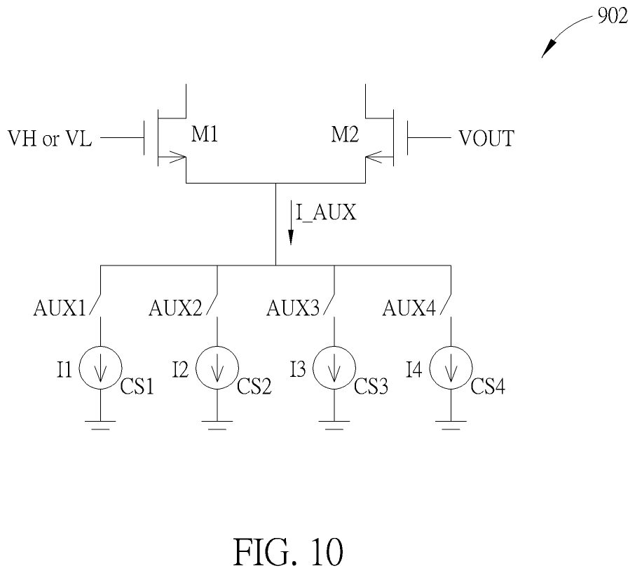

FIG. 10 illustrates an exemplary implementation of the auxiliary input pair 902, which includes two input transistors M1 and M2 receiving current supply from 4 VCCSs CS1-CS4. The input transistor M1 is configured to receive the high voltage VH or the low voltage VL, and the input transistor M2 is coupled to the output terminal of the SOP 90. The VCCSs CS1-CS4, which may be a component of the VCCSs 912 shown in FIG. 9, are coupled to the input transistors M1 and M2 through 4 switches AUX1-AUX4, respectively. The VCCSs CS1-CS4 are configured to supply currents I1-I4, respectively, to the auxiliary input pair 902, where the values of the currents I1-I4 may be controlled by the bias circuit 940 based on the trimming codes. Each of the switches AUX1-AUX4 may be turned on or off to generate a desired current value I_AUX supplied to the auxiliary input pair 902.

In an embodiment, the auxiliary input pair 902 may receive the high voltage VH or the low voltage VL according to the received data code DC, and the switches AUX1-AUX4 may be controlled according to the data code DC. An exemplary implementation is shown in Table 2. In this embodiment, the calibration is performed by using a 4-bit DDA operation as being controlled by the data code DC in a DDA cycle represented by a range from 0 (0000) to 15 (1111), where the error curve may have a pattern similar to that shown in FIG. 4. In detail, the minimum code (DC=0), the maximum code (DC=15), and the midmost code (DC=8) have no DDA error, and thus the switches AUX1-AUX4 are all turned off (denoted by 0) for these data codes and the auxiliary input pair 902 may be disabled. As for the lower half code range (DC=1˜7), there exists a negative DDA error, and thus the auxiliary input pair 902 receives the high voltage VH (i.e., VIN=VH) and a selected switch is turned on (denoted by 1) to supply the current value I_AUX, in order to slightly increase the output voltage VOUT of the SOP 90 to cancel the negative DDA error. As for the upper half code range (DC=9˜15), there exists a positive DDA error, and thus the auxiliary input pair 902 receives the low voltage VL (i.e., VIN=VL) and a selected switch is turned on (denoted by 1) to supply the current value I_AUX, in order to slightly decrease the output voltage VOUT of the SOP 90 to cancel the positive DDA error.

TABLE 2

| DC | VIN | I_AUX | AUX1 | AUX2 | AUX3 | AUX4 |
|---|---|---|---|---|---|---|
| 0 | VH | 0 | 0 | 0 | 0 | 0 |
| 1 | VH | I1 | 1 | 0 | 0 | 0 |
| 2 | VH | I2 | 0 | 1 | 0 | 0 |
| 3 | VH | I3 | 0 | 0 | 1 | 0 |
| 4 | VH | I4 | 0 | 0 | 0 | 1 |
| 5 | VH | I3 | 0 | 0 | 1 | 0 |
| 6 | VH | I2 | 0 | 1 | 0 | 0 |
| 7 | VH | I1 | 1 | 0 | 0 | 0 |
| 8 | VL | 0 | 0 | 0 | 0 | 0 |
| 9 | VL | I1 | 1 | 0 | 0 | 0 |
| 10 | VL | I2 | 0 | 1 | 0 | 0 |
| 11 | VL | I3 | 0 | 0 | 1 | 0 |
| 12 | VL | I4 | 0 | 0 | 0 | 1 |
| 13 | VL | I3 | 0 | 0 | 1 | 0 |
| 14 | VL | I2 | 0 | 1 | 0 | 0 |
| 15 | VL | I1 | 1 | 0 | 0 | 0 |

In this embodiment, the VCCS CS4 may supply the maximum current I4, which is greater than the currents I3, I2 and I1 sequentially, i.e., I4>I3>I2>I1. The values of the currents I1-I4 may be tuned to specific levels through the trimming operations, and an exemplary trimming result is shown in Table 3. In another embodiment, multiple switches may be turned on simultaneously to supply more possible current values for generating a more flexible and powerful calibration effect.

TABLE 3

| I1 | I2 | I3 | I4 |
|---|---|---|---|
| 4 nA | 8 nA | 10 nA | 12 nA |

Note that the present invention aims at providing a calibration circuit of a DDA for calibrating the linearity of the output voltage of the SOP. Those skilled in the art may make modifications and alterations accordingly. For example, in several embodiments, the error term for each input data code may be measured to obtain an appropriate trimming code. But in other embodiments, in order to simplify the operational costs, one measurement may be applied to several adjacent data code values, to apply the same trimming result for these data code values. For example, in the embodiment shown in FIG. 4, two adjacent data code values use the compensation value Comp1, and two adjacent data code values use the compensation value Comp2. In addition, in the above embodiments, one compensation value (bias voltage or current) corresponding to one trimming code may be obtained for a data code after measurement. In another embodiment, the trimming operations may be adaptive to PVT (process, voltage, temperature) variations. In other words, as for the same data code value, different trimming codes and different compensation values may be obtained under different environmental parameters, which may be affected by the manufacturing process, temperature, and/or data voltage level, thereby achieving more accurate calibration results.

In addition, in the input stage of different SOPs, the number of VCCSs for realizing the DDA operations may be different, and these VCCSs may have the same or different current values. The numerical values of the currents described above are merely an implementation of the output result generated from an exemplary trimming code, and these current values may be modified or adjusted under different trimming codes. The related implementations are not limited to those described in this disclosure.

To sum up, the present invention provides a calibration circuit of a DDA. The DDA operation is a technique applied in the SOP of the DDIC, where the SOP may generate an output voltage through interpolation by receiving a high voltage and a low voltage from the DAC. Several bits of the data code may be applied to realize the interpolation of the SOP, and thus the bit numbers required to be processed by the DAC may be reduced, thereby saving the size of the DAC. Since the output voltage generated through the DDA operation possesses a DDA error and might not be linear, a calibration scheme is necessary to compensate for the DDA error. The calibration circuit provided in the present invention may serve this purpose.

In an embodiment of the present invention, the calibration circuit may be implemented to adjust the current sources used for the input pairs of the SOP. Each of the current sources may be a VCCS controlled by a bias voltage, which may be tuned by using a trimming operation. By using a trimming code, the VCCSs may be adjusted to output appropriate current values so that the output voltage of the SOP will become more accurate (i.e., to be closer to the desired voltage value), so as to reduce the DDA error. In another embodiment, in addition to the basic input pairs originally existing in the input stage of the SOP, the input stage may also include one or more auxiliary input pairs. The auxiliary input pair(s) may selectively receive the high voltage or the low voltage, in order to generate an incremental value or a decremental value for the output voltage, so as to make the output voltage closer to its desired voltage value. The current supplied to the auxiliary input pair may be adjusted to an appropriate value by using the trimming code, to control the output voltage to accurately reach the desired voltage value. In such a situation, the output linearity of the SOP may be improved, and the possible bit number of the DDA operation may be increased without affecting the output linearity. As a result, the applicable voltage range of the DDA may be expanded, thereby decreasing the size of DACs and saving the circuit costs of the DDIC.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A calibration circuit of a differential difference amplifier (DDA), comprising:
a trimming circuit to output a trimming code;
a bias generator, coupled to the trimming circuit, to generate a bias current or voltage according to the trimming code; and
a compensation output circuit, coupled to the bias generator, to receive a data code of the DDA and output the bias current or voltage corresponding to the data code to the DDA.

2. The calibration circuit of claim 1, wherein the trimming circuit comprises a look-up table (LUT) to store a plurality of trimming codes corresponding to a plurality of data codes.

3. The calibration circuit of claim 2, wherein the compensation output circuit comprises a decoder to decode the data code to be used for the DDA, and the compensation output circuit selects the trimming code from the plurality of trimming codes according to the data code.

4. The calibration circuit of claim 1, wherein the compensation output circuit is further coupled to a latch circuit, to receive the data code from the latch circuit.

5. The calibration circuit of claim 1, wherein an input stage of the DDA comprises a plurality of current sources coupled to a plurality of input pairs, respectively, and the compensation output circuit outputs a first bias voltage to at least one of the plurality of current sources, to adjust an output current of the at least one current source.

6. The calibration circuit of claim 1, wherein an input stage of the DDA comprises a plurality of basic input pairs and an auxiliary input pair.

7. The calibration circuit of claim 6, wherein the compensation output circuit is coupled to the auxiliary input pair, to supply the bias current or voltage to the auxiliary input pair.

8. The calibration circuit of claim 6, wherein the compensation output circuit outputs a first bias voltage to a current source of the auxiliary input pair.

9. The calibration circuit of claim 6, wherein the compensation output circuit outputs a first bias current to the auxiliary input pair.

10. The calibration circuit of claim 1, wherein the trimming code is determined by measuring an output voltage of the DDA.
